(19) United States
(12) Patent Application Publication
(10) Pub. No.: US 2024/0079528 A1
(43) Pub. Date: Mar. 7, 2024

(54) DISPLAY DEVICE, METHOD OF MANUFACTURING THE DISPLAY DEVICE, AND VEHICLE INCLUDING THE DISPLAY DEVICE

(71) Applicant: Samsung Display Co., Ltd., Yongin-si (KR)

(72) Inventors: SANGWON EUN, Yongin-si (KR); YOUNGJU PARK, Yongin-si (KR); JOOSUB LEE, Yongin-si (KR); JINYOUNG LEE, Yongin-si (KR)

(21) Appl. No.: 18/342,663

(22) Filed: Jun. 27, 2023

(30) Foreign Application Priority Data
Aug. 29, 2022 (KR) 10-2022-0108218

(51) Int. Cl. H01L 33/44; B60K 35/00; H01L 33/52

(52) U.S. Cl. CPC H01L 33/44; B60K 35/00; H01L 33/52; B60K 2370/1529; H01L 2933/0025; H01L 2933/005

(57) ABSTRACT

A display device includes a display panel, an anti-reflection member on the display panel, a window member on the anti-reflection member, and an adhesive layer between the anti-reflection member and the window member. The adhesive layer may have a stress relaxation value of about 0.30 to about 0.40 with respect to a strain of about 24% to about 26%. Accordingly, the display device including the adhesive layer may exhibit excellent or suitable reliability.

### CROSS-REFERENCE TO RELATED APPLICATIONS

This application claims priority to and the benefit of Korean Patent Application No. 10-2022-0108218, filed on Aug. 29, 2022, in the Korean Intellectual Property Office, the entire content of which is hereby incorporated by reference.

### BACKGROUND

### 1. Field

Embodiments of the present disclosure relate to a display device including an adhesive layer, a method of manufacturing the display device including forming an adhesive layer, and/or a vehicle including the display device.

### 2. Description of Related Art

Various display devices used in devices such as automobiles, televisions, mobile phones, tablets, computers, navigation systems, and/or game consoles have been developed. Display devices provide an image having set or predetermined information to a user.

A display device includes a region in which an image is displayed and a region in which an image is not displayed. The region where the image is not displayed is perceived by the user as a bezel having a specific color. The bezel of the display device may be defined as a region in which a printing layer is disposed, and the printing layer may include a single or multi-layer structure in which a step is defined. An adhesive layer adjacent to the printing layer is usually required to have physical properties to cover the step in the printing layer.

The above information disclosed in this Background section is only for enhancing understanding of the background of the disclosure and therefore it may contain information that does not constitute prior art.

### SUMMARY

Aspects of one or more embodiments of the present disclosure are directed towards a display device including an adhesive layer having a stress relaxation value within a set or predetermined range.

Aspects of one or more embodiments of the present disclosure are also directed towards a method of manufacturing a display device including forming an adhesive layer from a preliminary adhesive layer having a creep value within a set or predetermined range.

Aspects of one or more embodiments of the present disclosure are also directed towards a vehicle including a display device which includes an adhesive layer having a stress relaxation value within a set or predetermined range.

Additional aspects will be set forth in part in the description which follows and, in part, will be apparent from the description, or may be learned by practice of the presented embodiments of the disclosure.

One or more embodiments of the present disclosure provides a display device including a display panel; an anti-reflection member on the display panel; a window member on the anti-reflection member; and an adhesive layer between the window member and the anti-reflection member, wherein the adhesive layer has a stress relaxation value of about 0.3 to about 0.4 with respect to a strain of about 24% to about 26%.

In one or more embodiments, the window member may include a window divided into a transmission region and a bezel region; and a printing layer that does not overlap the transmission region and is on one surface of the window; the adhesive layer being in contact with a side surface of the printing layer and one surface of the printing layer perpendicular to the side surface of the printing layer.

In one or more embodiments, in the bezel region the printing layer and the anti-reflection member may be spaced apart from each other with the adhesive layer therebetween.

In one or more embodiments, the adhesive layer may have a first thickness in the transmission region, and may have, in the transmission region, a second thickness greater than the first thickness.

In one or more embodiments, the printing layer may include first to third printing parts sequentially stacked on the one surface of the window, a first side surface of the third printing part and one surface of the second printing part may define a first step, and a second side surface of the second printing part and one surface of the first printing part may define a second step, and the adhesive layer may cover the first and the second step.

In one or more embodiments, the adhesive layer may include a polymer resin derived from the resin composition including a monomer, an oligomer and a crosslinking agent.

In one or more embodiments of the present disclosure, a method of manufacturing a display device includes preparing a resin composition including a monomer, an oligomer, and a crosslinking agent; forming a preliminary adhesive layer having a creep value of about 10% to about 35% with respect to a stress of about 900 Pa to about 1100 Pa by curing the resin composition; applying the preliminary adhesive layer on an anti-reflection member on a display panel; applying a window member on the preliminary adhesive layer on the anti-reflection prevention member; and forming an adhesive layer by curing the preliminary adhesive layer, wherein the adhesive layer may have a stress relaxation value of about 0.30 to about 0.40 with respect to a strain of about 24% to about 26%.

In one or more embodiments, in the forming of the adhesive layer, ultraviolet light of about 6500 mJ to about 8500 mJ may be applied to the preliminary adhesive layer.

In one or more embodiments, in the forming of the adhesive layer light may pass through the window member and is applied to the preliminary adhesive layer.

In one or more embodiments, the window member may include: a window divided into a transmission region and a bezel region; and a printing layer that does not overlap the transmission region and is on one surface of the window, the preliminary adhesive layer being in contact with a side surface of the printing layer and one surface of the printing layer being perpendicular to the side surface of the printing layer.

In one or more embodiments, the oligomer may have a weight of about 73.9 wt % to about 84.7 wt % with respect to a total weight of the resin composition.

In one or more embodiments, the oligomer may include 2-ethylhexyl acrylate (2-EHA).

In one or more embodiments, the monomer may have a weight of about 15.0 wt % to about 25.0 wt % with respect to the total weight of the resin composition.

In one or more embodiments, the monomer may include at least one of 2-Hydroxyethyl Acrylate (2-HEA), Butyl acrylate, Isooctyl acrylate, Isobornyl acrylate, octyl methacrylate, or Benzyl acrylate.

In one or more embodiments, the crosslinking agent may have a weight of about 15.0 wt % to about 25.0 wt % with respect to the total weight of the resin composition.

In one or more embodiments, the crosslinking agent may have a weight of about 0.1 wt % to about 0.5 wt % with respect to the total weight of the resin composition.

In one or more embodiments, the crosslinking agent may include at least one of 1,6-hexanediol diacrylate (HDDA), pentaerythritol triacrylate (PETA), tripropylene glycol diacrylate (TPGDA), dipropylene glycol diacrylate (DPGDA), tricyclodecane dimethanol diacrylate (TCDDA), tetraethylene glycol diacrylate (TTEGDA), bisphenol F (ethylene oxide)4 diacrylate, bisphenol A (ethylene oxide) 20 diacrylate, bisphenol A (ethylene oxide)30 diacrylate, polyethylene glycol 400 diacrylate (PEG400DA), polyethylene glycol 200 diacrylate (PEG200DA), polyethylene glycol 300 diacrylate (PEG300DA), polyethylene glycol 600 diacrylate (PEG600DA), or polypropylene glycol 400 diacrylate (PPG400DA).

In one or more embodiments, the resin composition may further include about 0.1 wt % to about 0.4 wt % of a photoinitiator with respect to the total weight of the resin composition.

In one or more embodiments, the resin composition may further include about 0.1 wt % to 0.2 wt % of a molecular weight modifier with respect to the total weight of the resin composition, and the molecular weight modifier may include n-dodecyl mercaptan.

In one or more embodiments, the resin composition may further include an ultraviolet (UV) absorber.

In one or more embodiments of the present disclosure provides a vehicle including: a first display device in a first region inside the vehicle and to display first information of the vehicle; and a second display device in a second region inside the vehicle and to display second information of the vehicle, wherein at least one of the first display device or the second display device includes: a display panel; an anti-reflection member on the display panel; a window member on the anti-reflection member; and an adhesive layer between the window member and the anti-reflection member; and wherein the adhesive layer has a stress relaxation value of about 0.30 to about 0.40 with respect to a strain of about 24% to about 26%.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain aspects, features and/or principles of the present disclosure. In the drawings:

FIG. 1 is a perspective view illustrating a display device according to one or more embodiments of the present disclosure;

FIG. 2 is a cross-sectional view illustrating a portion taken along line I-I′ in FIG. 1, according to one or more embodiments of the present disclosure;

FIG. 3 is an enlarged cross-sectional view of area XX′ of FIG. 2, according to one or more embodiments of the present disclosure;

FIG. 4 is a perspective view illustrating a display device according to one or more embodiments of the present disclosure;

FIG. 5 is a view illustrating the inside of a vehicle including a display device according to one or more embodiments of the present disclosure;

FIG. 6 is a flowchart illustrating a method of manufacturing a display device according to one or more embodiments of the present disclosure;

FIG. 7 is a schematic view illustrating an operation of a method of manufacturing the display device according to one or more embodiments of the present disclosure;

FIG. 8 is a schematic view illustrating an operation of a method of manufacturing the display device according to one or more embodiments of the present disclosure;

FIG. 9 is a schematic view illustrating an operation of a method of manufacturing the display device according to one or more embodiments of the present disclosure; and

FIG. 10 is a schematic view illustrating an operation of a method of manufacturing the display device according to one or more embodiments of the present disclosure;

### DETAILED DESCRIPTION

The present disclosure may be modified in many alternate forms, and thus specific embodiments will be illustrated in the drawing and described in more detail. It should be understood, however, that it is not intended to limit the present disclosure to the particular forms disclosed, but rather, is intended to cover all modifications, equivalents, and alternatives falling within the spirit and scope of the present disclosure.

It will be understood that when an element or layer is referred to as being “on”, “connected to” or “coupled to” another element or layer, it can be directly on, connected or coupled to the other element or layer or intervening elements or layers may be present. In addition, it will also be understood that when an element or layer is referred to as being “between” two elements or layers, it can be the only element or layer between the two elements or layers, or one or more intervening elements or layers may also be present.

Like numbers refer to like elements throughout, and duplicative descriptions thereof may not be provided. The thickness, ratio, and/or one or more dimensions of elements in the drawings may be exaggerated for clarity and/or effective description of the technical contents. As used herein, the term “and/or” includes any and all combinations of one or more of the associated listed items. As used herein, “/” may be interpreted as “and”, or as “or” depending on the context.

It will be understood that, although the terms first, second, etc. may be used herein to describe various elements, these elements should not be limited by these terms. These terms are only used to distinguish one element from another element. For example, a first element discussed below could be termed a second element, and similarly the second element could be termed the first element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and/or the like, may be used herein for ease of description to describe one element or feature's relationship to another element(s) or feature(s) as illustrated in the drawings. It will be understood that the spatially relative terms are intended to encompass different orientations of the device in use or operation in addition to the orientation depicted in the drawings.

Expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from a, b, and c,” “at least one from among a, b, and c,” “one from among a, b, and c”, “at least one of a to c” indicates only a, only b, only c, both a and b, both a and c, both b and c, all of a, b, and c, or variations thereof.

It will be further understood that the terms “comprises,” “includes” “comprising,” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

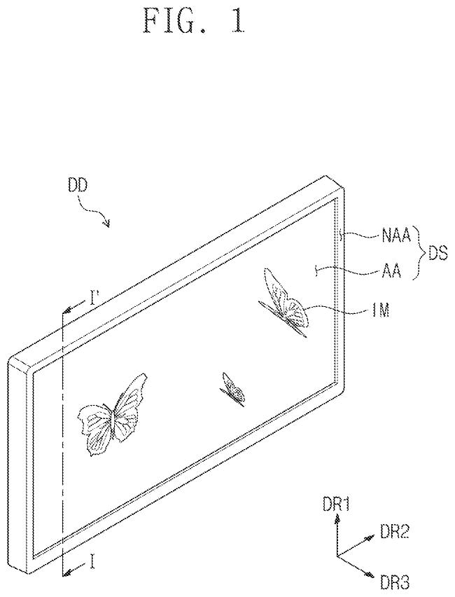

Hereinafter, a display device according to one or more embodiments will be described with reference to the accompanying drawings. FIG. 1 is a perspective view of a display device according to one or more embodiments of the present disclosure.

A display device DD according to one or more embodiments may be a device activated in response to an electrical signal. For example, the display device DD may be a display device utilized in a television, a monitor, an external billboard, or a vehicle. However, the present disclosure is not limited thereto, and the display device DD may be a display device utilized in small and medium-sized electronic devices such as personal computers, laptop computers, personal digital assistants, game consoles, portable electronic devices, and cameras. However, these are merely representative examples, and embodiments may include display devices utilized in other electronic devices without departing from the the present disclosure.

The display device DD may display an image IM through a display surface DS. The display surface DS may include an active region AA and a peripheral region NAA. The active region AA is a region in which pixels are substantially arranged to display the image IM. The active region AA may include a plane defined by a first direction axis DR1 and a second direction axis DR2 intersecting the first direction axis DR1. Although FIG. 1 illustrates that the active region AA has a rectangular shape, the shape of the active region AA may be variously modified according to the shape of the display device DD.

The peripheral region NAA may be a region in which the image IM is not displayed. The peripheral region NAA may surround the periphery of the active region AA. However, this is illustrated as an example and the peripheral region NAA may be disposed on only one or more sides of the active region AA.

The display device DD may sense an input through a user's body (e.g., a finger) or an input through an input device. The input device may refer to a device other than the user's body. For example, the input device may be an active pen, a stylus pen, a touch pen or an electronic pen. An input provided utilizing the user's body may include one or more suitable types (kinds) of external inputs such as touch, heat, or pressure provided utilizing a part of the user's body.

In one or more embodiments, the first direction axis DR1 and the second direction axis DR2 may be orthogonal to each other, and a third direction axis DR3 may indicate a direction of a line normal to a plane defined by the first direction axis DR1 and the second direction axis DR2. The thickness direction of the display device DD may be parallel to the direction in which the third direction axis DR3 extends. In one or more embodiments herein, a front surface (or an upper surface, an upper portion, another surface) and a rear surface (or a lower surface, a lower portion, one surface) of each member constituting the display device DD may be defined with respect to the third direction axis DR3. The front surface (or an upper surface, an upper portion, another surface) refer to a surface (or a direction) adjacent to the display surface DS, and the rear surface (or a lower surface, a lower portion, one surface) may refer to a surface (or a direction) spaced apart from the display surface DS.

The directions indicated by the first to third direction axes DR1, DR2, and DR3 described herein are relative concepts and may be changed into other directions. Additionally, the directions indicated by the first to third direction axes DR1, DR2, and DR3 may be described as first to third direction, and like reference numerals or symbols may be used.

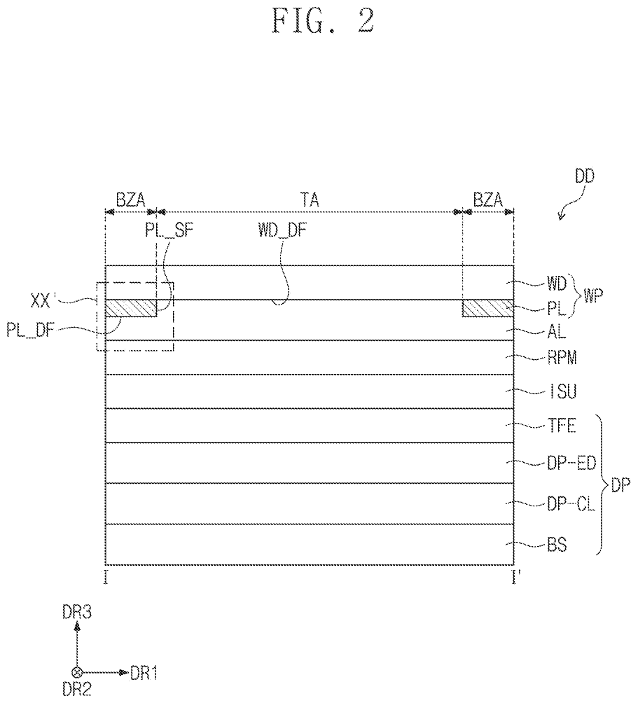

FIG. 2 is a cross-sectional view illustrating a portion taken along line I-I′ of FIG. 1, and is a cross-sectional view of a display device according to one or more embodiments of the present disclosure. The display device DD according to one or more embodiments may include a display panel DP, an anti-reflection member RPM disposed on the display panel DP, a window member WP disposed on the anti-reflection member RPM, and an adhesive layer AL disposed between the anti-reflection member RPM and the window member WP. Additionally, the display device DD may further include an input sensing layer ISU disposed on the display panel DP.

The display panel DP may be an organic light emitting display panel, an inorganic light emitting display panel, a quantum dot display panel, a micro-LED display panel, a nano LED display panel, or a liquid crystal display panel. Referring to FIG. 2, the display panel DP may include a base layer BS, a circuit layer DP-CL, a display element layer DP-ED, and an encapsulation layer TFE which are stacked in sequence. However, the configuration of the display panel DP illustrated in FIG. 2 etc., is illustrated by way of example and the present disclosure is not limited thereto. For example, when the display panel DP is a liquid crystal display panel, the encapsulation layer TFE may not be provided.

The base layer BS may be a member providing a base surface on which the circuit layer DP-CL is disposed. The base layer BS may be a rigid substrate or a flexible substrate capable of bending, folding, or rolling. The base layer may be a glass substrate, a metal substrate, or a polymer substrate. However, the present disclosure is not limited thereto, and the base layer BS may include an inorganic layer, an organic layer or a composite material layer.

The base layer BS may have a multilayer structure. For example, the base layer BS may have a three-layer structure of a synthetic resin layer, an adhesive layer, and a synthetic resin layer. In particular, the synthetic resin layer may include a polyimide-based resin. Also, the synthetic resin layer may include at least one of an acrylate-based resin, a methacrylate-based resin, a polyisoprene-based, a vinyl-based resin, an epoxy-based resin, a urethane-based resin, a cellulose-based resin, a siloxane-based resin, a polyamide-based resin or a perylene-based. In the present disclosure, “˜˜-based” resin means including a functional group of “˜˜”.

The circuit layer DP-CL may include a plurality of transistors. Each of the transistors may include a control electrode, an input electrode, and an output electrode. For example, the circuit layer DP-CL may include a switching transistor and a driving transistor for driving a light emitting element of the display element layer DP-ED. Also, the circuit layer DP-CL may include an insulating layer, a semiconductor pattern, a conductive pattern, and a signal line and etc.

The display element layer DP-ED may include a light emitting element. For example, the light emitting element may include an organic light emitting material, an inorganic light emitting material, an organic-inorganic light emitting material, quantum dots, quantum roads, a micro-LED or a nano-LED.

The encapsulation layer TFE may cover the display element layer DP-ED. The encapsulation layer TFE may seal the display element layer DP-ED. The encapsulation layer TFE may be a thin-film encapsulation layer. The encapsulation layer TFE may be a single layer or a stack of a plurality of layers. The encapsulation layer TFE may include at least one insulation layer. The encapsulation layer TFE may include at least one inorganic film (hereinafter, an inorganic encapsulation film). Also, the encapsulation layer TFE may include at least one organic film (hereinafter, an organic encapsulation film) and at least one inorganic encapsulation film.

The inorganic encapsulation film may protect the display element layer DP-ED from moisture/oxygen, and the organic encapsulation film may protect the display element layer DP-ED from foreign substances such as dust particles. The inorganic encapsulation film may include silicon nitride, silicon oxynitride, silicon oxide, titanium oxide, or aluminum oxide; however, the present disclosure is not limited thereto. The organic encapsulation film may include an acryl-based compound, an epoxy-based compound, and/or the like. The organic encapsulation film may include a photopolymerizable organic material; however, the present disclosure is not particularly limited thereto.

The input sensing layer ISU may be directly disposed on the encapsulation layer TFE. The input sensing layer ISU may sense an external input, convert the external input into a set or predetermined input signal, and provide the input signal to the display panel DP. For example, in the display device DD according to one or more embodiments, the input sensing layer ISU may be a touch sensing unit for sensing a touch. The input sensing layer ISU may recognize a direct touch of a user, an indirect touch of a user, a direct touch of an object, or an indirect touch of an object.

The input sensing layer ISU may sense at least one of the position or intensity (pressure) of a touch which is applied from the outside. The input sensing layer ISU may have one or more suitable structures or be composed of one or more suitable materials; however, the present disclosure is not limited to any one embodiment. The input sensing layer ISU may include a plurality of sensing electrodes for sensing an external input. The sensing electrodes may sense an external input in a capacitive manner. The display panel DP may receive an input signal from the input sensing layer ISU and generate an image corresponding to the input signal.

The anti-reflection member RPM may be disposed on the input sensing layer ISU. The anti-reflection member RPM may control reflected light of external light from the display panel DP. For example, the anti-reflection member RPM may include a polarization layer. In one or more embodiments, an auxiliary adhesive layer may be disposed between the input sensing layer ISU and the anti-reflection member RPM. The auxiliary adhesive layer may include an adhesive generally available and/or suitable in the art, and the present disclosure is not limited to any one embodiment or any particular adhesive material.

The window member WP may include a window WD and a printing layer PL. The window WD may be divided into a transmission region TA and a bezel region BZA. The transmission region TA may be optically transparent. The bezel region BZA may have a relatively low light transmittance compared to the transmission region TA. The bezel region BZA may have a set or predetermined color. The bezel region BZA may be adjacent to the transmission region TA and may surround the transmission region TA. The bezel region BZA may define the shape of the transmission region TA. However, the present disclosure is not limited thereto and the bezel region BZA may be disposed adjacent to only one side of the transmission region TA.

The transmission region TA may correspond to the active region AA of the display device DD illustrated in FIG. 1. The bezel region BZA may correspond to the peripheral region NAA of the display device DD illustrated in FIG. 1. In this specification, the wording, “one component and another component overlap/correspond” is not limited to having the same shape and the same area, and includes cases where the two components have different shapes and/or different areas.

The window WD may include a glass or plastic substrate. The window WD may be optically transparent. For example, a tempered glass substrate may be utilized for the window WD. In one or more embodiments, the window WD may be made of a flexible polymer resin. For example, the window WD may be made of polyimide, polyacrylate, polymethylmethacrylate, polycarbonate, polyethylenenaphthalate, polyvinylidene chloride, polyvinylidene difluoride, polystyrene, ethylene vinylalcohol copolymer or a combination thereof. However, this is illustrated by way of example and the present disclosure is not limited thereto.

The printing layer PL may be disposed on one surface WD_DF of the window WD. The one surface WD_DF of the window WD may be a lower surface of the window WD adjacent to the display panel DP. The printing layer PL may be disposed on a periphery of the window WD. The printing layer PL may be an ink printing layer. Also, the printing layer PL may be a layer formed including a pigment and/or a dye. The bezel region BZA may be a portion where the printing layer PL is provided.

The printing layer PL may not overlap the transmission region TA. The printing layer PL may overlap at least a portion of the bezel region BZA.

In one or more embodiments, the window member WP may further include at least one functional layer disposed on the window WD. For example, the functional layer may be a hard coating layer, an anti-fingerprint coating layer, etc., but the present disclosure is not limited thereto.

The adhesive layer AL may be optically transparent. For example, the adhesive layer may include an optically clear adhesive (OCA).

The window member WP and the anti-reflection member RPM may be bonded to each other by the adhesive layer AL. In one or more embodiments, the adhesive layer AL may have a stress relaxation value of about 0.30 to about 0.40 with respect to a strain of about 24% to about 26%. For example, the stress relaxation value of the adhesive layer AL with respect to a strain of about 24% to about 26% may be about 0.32 to about 0.34. In the present specification, the stress relaxation value of the adhesive layer AL is measured with Rheometer ARES produced by TA instrument, Inc., at a strain of about 24% to about 26% and a temperature of about 70° C. More specifically, the stress relaxation value of the adhesive layer AL is a value obtained by dividing a second stress by a first stress. The first stress is a stress in a state in which a strain of about 25% is applied for about 0.01 seconds, and the second stress is a stress in a state in which a strain of about 25% is applied for about 300 seconds. The adhesive layer AL having a stress relaxation value of about 0.32 to about 0.34 at a temperature of about 70° C. may exhibit excellent or suitable reliability at high temperatures.

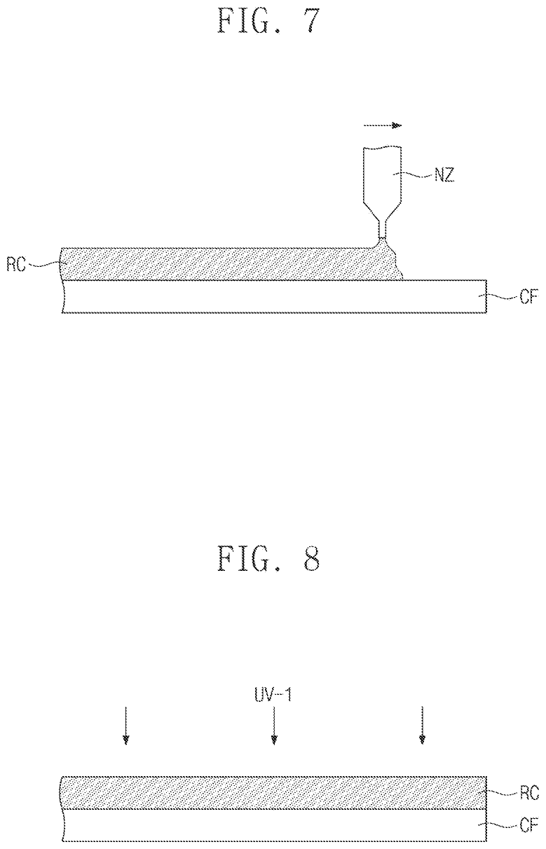

In one or more embodiments, the adhesive layer AL may include a polymer resin derived from a resin composition RC (see, e.g., FIG. 7) to be described in more detail later, and the resin composition RC (see, e.g., FIG. 7) may include a monomer, an oligomer, and a crosslinking agent. The monomer and the oligomer may be crosslinked to form the adhesive layer AL, and the stress relaxation value of the adhesive layer AL may be proportional to the crosslinking density. The higher the stress relaxation value, the higher the crosslinking density. As the crosslinking density is high, it is possible to prevent or reduce the introduction of foreign substances and the generation of bubbles, and to have high reliability at high temperatures. On the other hand, in an adhesive layer having a stress relaxation value less than about 0.30, foreign substances may be introduced or bubbles may be generated, and in an adhesive layer having a stress relaxation value greater than about 0.40, cracks may occur. In one or more embodiments, the adhesive layer AL having a stress relaxation value of about 0.30 to about 0.40 with respect to a strain of about 24% to about 26% may exhibit excellent or suitable crosslinking density. Accordingly, the display device DD including the adhesive layer AL according to one or more embodiments may exhibit excellent or suitable reliability.

Referring to FIG. 2, the adhesive layer AL may contact a side surface PL_DF of the printing layer PL and one surface PL_DF of the printing layer PL. The one surface PL_DF of the printing layer PL may be perpendicular to or crossing the side surface PL_DF of the printing layer PL and may be a lower surface of the printing layer PL adjacent to the display panel DP. In the bezel region BZA, the printing layer PL and the anti-reflection member RPM may be apart (e.g., spaced apart or separated) from each other with the adhesive layer AL therebetween. In the transmission region TA, the window WD and the anti-reflection member RPM may be apart (e.g., spaced apart or separated) from each other with the adhesive layer AL therebetween.

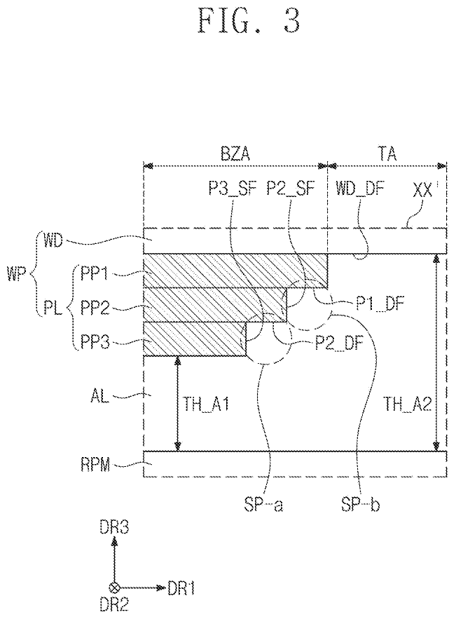

FIG. 3 is an enlarged cross-sectional view of area XX′ of FIG. 2, according to one or more embodiments of the present disclosure. Referring to FIG. 3, the adhesive layer AL may have a first thickness TH_A1 in the bezel region BZA and a second thickness TH_A2 in the transmission region TA. The second thickness TH_A2 may be greater than the first thickness TH_A1. Each of the first thickness TH_A1 and the second thickness TH_A2 may be about 100 μm to about 350 μm. An adhesive layer having a thickness of less than 100 μm has low adhesion reliability, and an adhesive layer having a thickness of greater than 350 μm results in an increase in the thickness of the display device. In one or more embodiments, the adhesive layer AL having the thicknesses TH_A1 and TH_A2 of about 100 μm to about 350 μm has excellent or suitable adhesion reliability and minimizes or reduces an increase in the thickness of the display device DD.

The adhesive layer AL may be disposed on the lower surface PL_DF (see, e.g., FIG. 2) of the printing layer PL in the bezel region BZA, and may be disposed on the lower surface WD_DF (see, e.g., FIG. 2) of the window WD in the transmission region TA. Accordingly, the adhesive layer AL may have different thicknesses TH_A1 and TH_A2 in the bezel region BZA and in the transmission region TA. The lower surface of the adhesive layer AL adjacent to the anti-reflection member RPM may be a flat surface.

In one or more embodiments, the printing layer PL may include a multi-layered structure. The printing layer PL may include first to third printing parts PP1, PP2, and PP3 sequentially stacked on one surface WD_DF of the window WD. The first printing part PP1 may be directly disposed on the one surface WD_DF (see, e.g., FIGS. 2 and 3) of the window WD. In the thickness direction DR3, the third printing part PP3 may be disposed on the adhesive layer AL, the second printing part PP2 may be disposed on the third printing part PP3, and the first printing part PP1 may be disposed on the second printing part PP2. In the thickness direction DR3, the window WD may be disposed on the first printing part PP1. Among the first to third printing parts PP1, PP2, and PP3, the third printing part PP3 is closest to the anti-reflection member RPM, and the first printing part PP1 may be the farthest apart (e.g., spaced apart or separated) from the anti-reflection member RPM.

For example, the printing layer PL may be obtained through a three-color process. The first to third printing parts PP1, PP2, and PP3 may be respectively formed by providing inks of different colors. However, this is illustrated by way of example, and at least two printing parts among the first to third printing parts PP1, PP2 and PP3 may be formed by providing ink of the same color.

On a plane defined by the first direction axis DR1 and the second direction axis DR2, the first printing part PP1, the second printing part PP2, and the third printing part PP3 may have different areas. The first printing part PP1 adjacent to the window WD may have the largest area, and the third printing part PP3 adjacent to the adhesive layer AL may have the smallest area. On a plane defined by the first direction axis DR1 and the second direction axis DR2, the area of the first printing part PP1 may be the same as the area of the bezel region BZA. However, the present disclosure is not limited thereto, and the areas and arrangement locations of the first to third printing parts PP1, PP2, and PP3 may be changed.

Referring to FIG. 3, the length of the first printing part PP1 in the first direction DR1 may be the same as the length of the bezel region BZA. The length of the second printing part PP2 and the length of the third printing part PP3 in the first direction DR1 may be shorter than the length of the bezel region BZA. Accordingly, a first step SP-a and a second step SP-b may be defined by the first to third printing parts PP1, PP2, and PP3.

The first step SP-a may be defined by the first side surface P3_SF of the third printing part PP3 and the one surface P2_DF of the second printing part PP2. The second step SP-b may be defined by the second side surface P2_SF of the second printing part PP2 and the one surface P1_DF of the first printing part PP1. The adhesive layer AL may cover the first step SP-a and the second step SP-b. The adhesive layer AL may contact the first side surface P3_SF of the third printing part PP3 and the one surface P2_DF of the second printing part PP2. The adhesive layer AL may contact the second side surface P2_SF of the second printing part PP2 and the one surface P1_DF of the first printing part PP1. One surface P2_DF of the second printing part PP2 may be a lower surface of the second printing part PP2. One surface P1_DF of the first printing part PP1 may be a lower surface of the first printing part.

In a method of manufacturing a display device according to one or more embodiments to be described in more detail later, the adhesive layer AL may be formed from a preliminary adhesive layer P-AL (see, e.g., FIG. 10), and the preliminary adhesive layer P-AL may be formed from the resin composition RC (see, e.g., FIG. 7) The preliminary adhesive layer P-AL according to one or more embodiments may satisfy a set or predetermined creep value. Accordingly, the preliminary adhesive layer P-AL may cover the first step SP-a and the second step SP-b defined by the first to third printing parts PP1, PP2, and PP3. The adhesive layer AL formed from the preliminary adhesive layer P-AL may cover the first step SP-a and the second step SP-b.

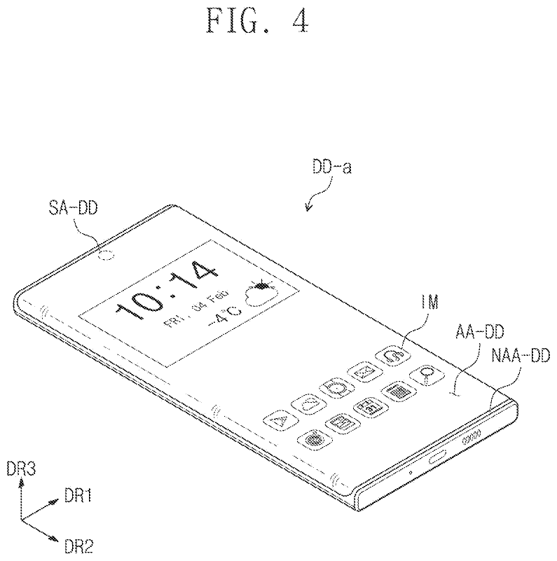

FIG. 4 illustrates a display device according to one or more embodiments of the present disclosure, in which a display device DD-a is a smartphone. The display device DD-a of FIG. 4 may include the same or similar components as those of the display device DD described with reference to FIGS. 2 and 3.

Referring to FIG. 4, the display device DD-a may include an active region AA-DD and a peripheral region NAA-DD adjacent to the active region AA-DD. The active region AA-DD may be a region in which an image IM is displayed. The active region AA-DD may include a plane defined by a first direction axis DR1 and a second direction axis DR2 crossing the first direction axis DR1. The peripheral region NAA-DD may be a region in which the image IM is not displayed.

A sensing region SA-DD may be defined in the active region AA-DD of the display device DD-a. Although one sensing region SA-DD is illustrated in FIG. 4, the number of sensing regions SA-DD is not limited thereto. The sensing region SA-DD may be a part of the active region AA-DD. The display device DD-a may display the image through the sensing region SA-DD.

In one or more embodiments, an optical signal, for example, visible light or infrared light, may propagate to the sensing region SA-DD. The display device DD-a may include an electronic module that captures an external image through visible light passing through the sensing region SA-DD or determines an approach of an external object through infrared light.

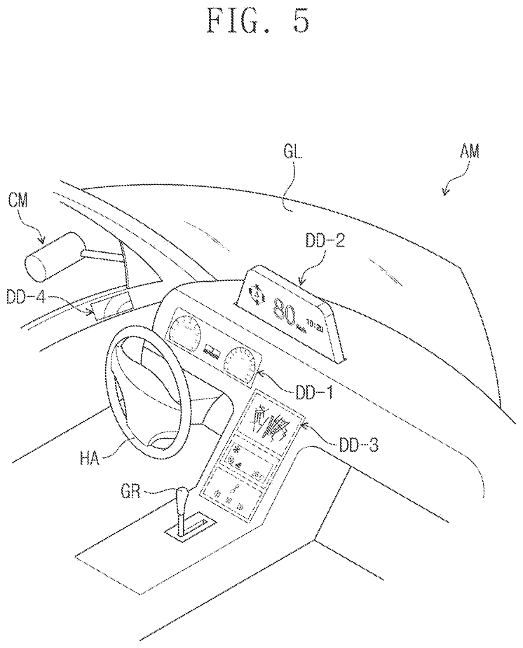

The display device DD (see, e.g., FIG. 2) according to one or more embodiments may be included in at least one of display devices DD-1, DD-2, DD-3, and/or DD-4 disposed inside a vehicle AM. FIG. 5 illustrates first to fourth display devices DD-1, DD-2, DD-3, and DD-4 disposed inside the vehicle AM. Although an automobile is illustrated as a vehicle AM in FIG. 5, this is illustrated by way of example, and the first to fourth display devices DD-1, DD-2, DD-3, and DD-4 may be disposed on other transportation apparatuses such as bicycles, motorcycles, trains, ships, airplanes, and/or the like. At least one of the first to fourth display devices DD-1, DD-2, DD-3, and DD-4 may have the same configuration as the display device DD described with reference to FIGS. 2 and 3.

In one or more embodiments, at least one of the first to fourth display devices DD-1, DD-2, DD-3, and/or DD-4 may include the display panel DP (see, e.g., FIG. 3), the anti-reflection member RPM (see, e.g., FIG. 3) disposed on the display panel DP (see, e.g., FIG. 3), the window member WP (see, e.g., FIG. 3) disposed on the anti-reflection member RPM, and the adhesive layer AL disposed between the window member WP (see, e.g., FIG. 3) and the anti-reflection member RPM (see, e.g., FIG. 3). The adhesive layer AL included in at least one of the first to fourth display device DD-1, DD-2, DD-3, and/or DD-4 may have a stress relaxation value of about 0.30 to about 0.40 with respect to a strain of about 24% to about 26%. In one or more embodiments, at least one of the first to fourth display devices DD-1, DD-2, DD-3, or DD-4 includes an adhesive layer AL having a stress relaxation value of about 0.30 to about 0.4 with respect to a strain of about 24% to about 26% and may exhibit excellent or suitable reliability.

Referring to FIG. 5, the vehicle AM may include a steering wheel HA and a gear GR for operation of the vehicle AM, and a front window GL may be disposed to face the driver.

The first display device DD-1 may be disposed in a first region overlapping the steering wheel HA. For example, the first display device DD-1 may be a digital cluster displaying first information of the vehicle AM. The first information may include a first scale indicating a traveling speed of the vehicle AM, a second scale indicating a rotation speed of an engine (e.g., revolutions per minute (RPM)), and an image indicating a fuel state. The first scale and the second scale may be displayed as digital images.

The second display device DD-2 may be disposed in a second area facing a driver's seat and overlapping the front window GL. The driver's seat may be a seat on which the steering wheel HA is disposed. For example, the second display device DD-2 may be a head up display (HUD) that displays second information of the vehicle AM. The second display device DD-2 may be optically transparent. The second information includes a digital number indicating the traveling speed of the vehicle AM, and may further include information such as a current time. In one or more embodiments, the second information of the second display device DD-2 may be projected and displayed on the front window GL.

The third display device DD-3 may be disposed in a third region adjacent to the gear GR. For example, the third display device DD-3 may be a center information display (CID) disposed between a driver's seat and a passenger seat, and displaying third information. The passenger seat may be a seat apart (e.g., spaced apart or separated) from the driver's seat with the gear GR therebetween. The third information may include information pertaining to road conditions (e.g., navigation information), music or radio playback, dynamic image playback, the internal temperature of the vehicle AM, etc.

The fourth display device DD-4 may be apart (e.g., spaced apart or separated) from the steering wheel HA and the gear GR, and disposed in a fourth region adjacent to the side of the vehicle AM. For example, the fourth display device DD-4 may be a digital side mirror that displays fourth information. The fourth display device DD-4 may display an external image of the vehicle AM captured by a camera module CM disposed outside the vehicle AM. The fourth information may include an external image of the vehicle AM.

The first to fourth information described above are illustrated by way of example, and the first to fourth display devices DD-1, DD-2, DD-3, and DD-4 may further display information regarding the interior and exterior of the vehicle. The first to fourth information may include different pieces of information. However, the present disclosure is not limited thereto, and some pieces of the first to fourth information may include the same information.

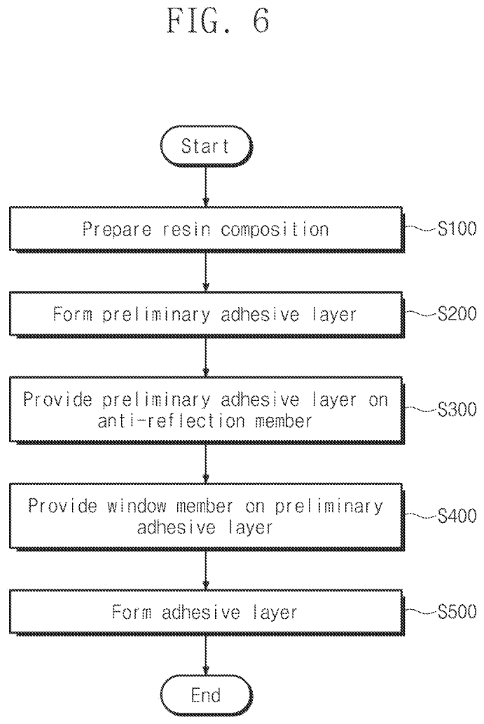

At least one among the display devices DD and/or DD-a, and/or the first to fourth display devices DD-1, DD-2, DD-3, and DD-4 according to embodiments may be manufactured by a method of manufacturing the display device according to one or more embodiments of the present disclosure. FIG. 6 is a flowchart illustrating a method of manufacturing a display device according to one or more embodiments of the present disclosure, and FIGS. 7 to 10 schematically illustrate operation of the method of manufacturing the display device according to one or more embodiments of the present disclosure. Hereinafter, in the description of the method of manufacturing a display device according to one or more embodiments described with reference to FIGS. 7 to 10, content that is duplicative of the content described with reference to FIGS. 1 to 5 may not be given again, and the following description will mainly focus on differences.

The method of manufacturing a display device according to one or more embodiments may include preparing a resin composition (S100), forming a preliminary adhesive layer (S200), providing the preliminary adhesive layer on an anti-reflection member (S300), providing a window member on the preliminary adhesive layer (S400), and forming an adhesive layer (S500).

The resin composition RC according to one or more embodiments may include a monomer, an oligomer, and a crosslinking agent. The weight of the monomer may be about 15.0 wt % to about 25.0 wt % with respect to the total weight of the resin composition RC. For example, the monomer may include at least one of 2-hydroxyethyl acrylate (2-HEA), butyl acrylate, isooctyl acrylate, isobornyl acrylate, octyl methacrylate, or benzyl acrylate.

The weight of the oligomer may be about 73.9 wt % to about 84.7 wt % with respect to the total weight of the resin composition RC. For example, the oligomer may include 2-ethylhexyl acrylate (2-HEA). The preliminary adhesive layer P-AL formed from the resin composition RC including the monomer and oligomer satisfying the above-described weight ranges may have a creep value according to one or more embodiments of the present disclosure.

In one or more embodiments, with respect to the total weight of the resin composition, the weight of the crosslinking agent may be about 0.1 wt % to about 0.5 wt %. The adhesive layer AL formed from the resin composition RC including the crosslinking agent in an amount of about 0.1 wt % to about 0.5 wt % may satisfy the stress relaxation value range according to one or more embodiments of the present disclosure. A stress relaxation value of the adhesive layer AL according to one or more embodiments may be about 0.30 to about 0.40. On the other hand, an adhesive layer formed from a resin composition including a crosslinking agent in an amount of less than about 0.1 wt % exhibits a stress relaxation value of less than about 0.30 due to insufficient crosslinking between the monomer and the oligomer. In one or more embodiments, an adhesive layer formed from a resin composition including a crosslinking agent in an amount more than about 0.5 wt % exhibits a stress relaxation value of more than about 0.40 due to excessive crosslinking between the monomer and the oligomer.

For example, the crosslinking agent may include at least one of 1,6-hexanediol diacrylate (HDDA), pentaerythritol triacrylate (PETA), tripropylene glycol diacrylate (TPGDA), dipropylene glycol diacrylate (DPGDA), tricyclodecane dimethanol diacrylate (TCDDA), tetraethylene glycol diacrylate (TTEGDA), bisphenol F (ethylene oxide)₄ diacrylate, bisphenol A (ethylene oxide)₂₀ diacrylate, bisphenol A (ethylene oxide)₃₀ diacrylate, polyethylene glycol 400 diacrylate (PEG400DA), polyethylene glycol 200 diacrylate (PEG200DA), polyethylene glycol 300 diacrylate (PEG300DA), polyethylene glycol 600 diacrylate (PEG600DA), or polypropylene glycol 400 diacrylate (PPG400DA). An adhesive layer AL formed from the resin composition RC including a crosslinking agent including at least one of the materials described above may exhibit excellent or suitable reliability.

Referring to FIG. 7, the resin composition RC may be provided on a substrate CF. The substrate is a member utilized temporarily and is not limited to any one embodiment or any particular material. Any component, on which it is easy to provide the resin composition RC and detach the preliminary adhesive layer P-AL formed from the resin composition RC may be utilized as the substrate CF. Although FIG. 7 illustrates that the resin composition RC is provided through a nozzle NZ, a method of providing the resin composition RC is not limited thereto.

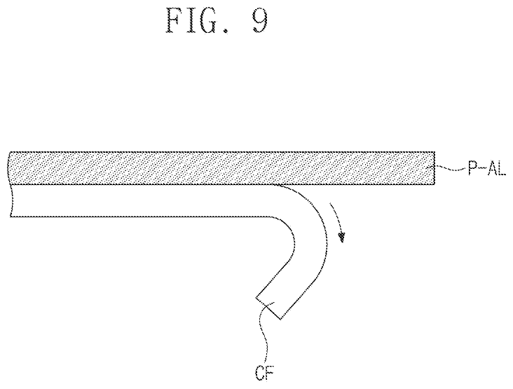

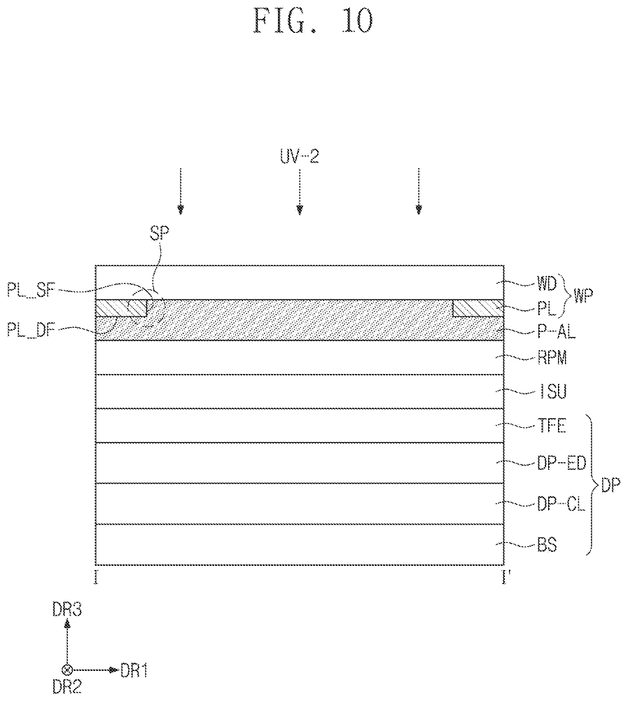

Referring to FIG. 8 and FIG. 9, the resin composition RC may be cured and thus the preliminary adhesive layer P-AL may be formed. The resin composition RC may be cured by first light UV-1, and the provided first light UV-1 may be ultraviolet light. Although it is illustrated in FIG. 8 that the first light UV-1 is provided directly to the resin composition RC, the present disclosure is not limited thereto. The first light UV-1 may be provided after a carrier film is disposed on the resin composition RC applied on the substrate CF. The carrier film allows first light UV-1 to pass therethrough.

The preliminary adhesive layer may have a curing rate of about 90% or less. The curing rate of the preliminary adhesive layer may be calculated utilizing a gel fraction measurement method. The preliminary adhesive layer P-AL is immersed in a solvent of ethyl acetate (EA), and in this case, the weight ratio of the preliminary adhesive layer P-AL to ethyl acetate (EA) is about 1:1000. Then, by measuring the weight after one day has passed, the curing rate of the preliminary adhesive layer P-AL may be confirmed. The monomer and/or the oligomer remaining unreacted in the preliminary adhesive layer P-AL may be dissolved in a solvent, and as the monomer and/or the oligomer are dissolved, the weight of the preliminary adhesive layer P-AL may be reduced. The curing rate may be calculated from a weight change ratio of the preliminary adhesive layer P-AL.

Referring to FIG. 9 and FIG. 10, the preliminary adhesive layer P-AL may be detached from the substrate CF and provided on the anti-reflection member RPM. The window member WP may be provided on the preliminary adhesive layer P-AL disposed on the anti-reflection member RPM.

The preliminary adhesive layer P-AL may have a creep value of about 10% to about 35% with respect to a stress of about 900 Pa to about 1100 Pa. For example, the preliminary adhesive layer P-AL may have a creep value of about 10.7% to about 33.3%. In embodiments of the present disclosure, the creep value of the preliminary adhesive layer was measured with a Rheometer ARES produced by TA instrument, Inc., when a stress of about 900 Pa to about 1100 Pa was applied for about 175 seconds at a temperature of about 50° C.

A preliminary adhesive layer P-AL having a creep value of less than about 10% may not cover a step SP in the printing layer PL, thus stress may be concentrated on the step SP, and bubbles may be generated in the peripheral portion. The preliminary adhesive layer P-AL having a creep value of less than 10% may have relatively lower softness. A preliminary adhesive layer P-AL having a creep value of more than about 35% does not retain its shape and may cause defect. In one or more embodiments, a preliminary adhesive layer P-AL having a creep value of about 10% to about 35% may cover the step SP of the printing layer PL. The preliminary adhesive layer P-AL may be in contact with a side surface PL_SF of the printing layer PL and one surface PL_DF of the printing layer PL (see, e.g., FIG. 2). The one surface PL_DF of the printing layer PL may be perpendicular to the side surface PL_SF of the printing layer PL (see, e.g., FIG. 2).

The step SP illustrated in FIG. 10 schematically represents the first and second step SP-a, SP-b illustrated in FIG. 3. The adhesive layer AL (see, e.g., FIGS. 2 and 3) formed from the preliminary adhesive layer P-AL having a creep value of about 10% to about 35% may exhibit excellent or suitable reliability.

The second light UV-2 may be provided to the preliminary adhesive layer P-AL to form the adhesive layer AL. A curing rate of the adhesive layer AL may be 100% or less. The curing rate of the adhesive layer AL may be calculated in substantially the same way as the above-described method of calculating the curing rate of the preliminary adhesive layer P-AL.

After the window member WP is disposed on the preliminary adhesive layer P-AL, the second light UV-2 may be provided. The window member WP may be a member allowing the second light UV-2 to pass therethrough. The second light UV-2 may be ultraviolet light. The second light UV-2 of about 6500 mJ to about 8500 mJ may be provided to the preliminary adhesive layer P-AL. The adhesive layer AL formed by providing ultraviolet light UV-2 of about 6500 mJ to about 8500 mJ may have a stress relaxation value of about 0.30 to about 0.40 with respect to a strain of about 24% to about 26%. As described above, the adhesive layer AL having a high stress relaxation value may exhibit more excellent or suitable crosslinking density. Therefore, the adhesive layer AL formed by providing ultraviolet light UV-2 of about 6500 mJ to about 8500 mJ may have an excellent or suitable crosslinking density.

When light is provided to the resin composition RC, the monomer and the oligomer may be crosslinked, and crosslinking between the monomer and the oligomer may form a preliminary adhesive layer P-AL and an adhesive layer AL. Crosslinking between the monomer and the oligomer may be controlled or selected according to the amount of light provided, and increasing the amount of light provided may result in an increase in crosslinking between the monomer and the oligomer. As the crosslinking of the monomer and the oligomer increases, the crosslinking density of the adhesive layer AL may be improved. As the crosslinking density is improved, introduction of foreign substances and generation of bubbles in the adhesive layer AL may be prevented or reduced. Accordingly, the adhesive layer AL formed by providing ultraviolet light UV-2 of about 6500 mJ to about 8500 mJ to the preliminary adhesive layer P-AL may exhibit excellent or suitable reliability.

The method of manufacturing a display device according to one or more embodiments may include forming a preliminary adhesive layer satisfying a set or predetermined creep value, and forming an adhesive layer satisfying a set or predetermined stress relaxation value. Accordingly, the method of manufacturing a display device according to one or more embodiments may exhibit improved manufacturing reliability.

The resin composition RC may further include a photoinitiator. With respect to the total weight of the resin composition RC, the weight of the photoinitiator may be about 0.1 wt % to about 0.4 wt %. The adhesive layer AL formed from the resin composition RC including about 0.1 wt % to about 0.4 wt % of the photoinitiator may exhibit excellent or suitable reliability. The photoinitiator may include a radical polymerization initiator. When the resin composition RC includes a plurality of photoinitiators, different photoinitiators may be respectively activated by ultraviolet light having different central wavelengths.

For example, the photoinitiator may be any one of 2,2-dimethoxy-1,2-diphenylethan-1-one, 1-hydroxycyclohexyl-phenyl-ketone (Irgacure 184), benzyldimethyl ketal (Irgacure 651), 2-hydroxy-2-methyl-1-phenyl-1-propanone), 2-hydroxy-1-[4-(2-hydroxyethoxy)phenyl]-2-methyl-1-propanone, or 2-hydroxy-1-{4-[4-(2-hydroxy-2-methyl-propionyl)-benzyl]-phenyl}-2-methylpropan-1-one).

Also, the photoinitiator may be any one of 4-hydroxy benzophenone, Alpha, alpha-dimethoxy-alphaphenylacetophenone, 2-methyl-1[4-(methylthio)phenyl]-2-morpholinopropan-1-one, 2-benzyl-2-dimethylamino-1-(4-morpholinophenyl)-butanone-1, 2-dimethylamino-2-(4-methyl-benzyl)-1-(4-morpholin-4-ylphenyl)-butan-1-one, 2,4,6-trimethylbenzoyl-diphenylphosphine oxide, ethyl(2,4,6-trimethylbenzoyl)-phenyl phosphinate, bis(2,4,6-trimethylbenzoyl)-phenylphosphineoxide, [1-(4-phenylsulfanylbenzoyl)heptylideneamino]benzoate, [1-[9-ethyl-6-(2-methylbenzoyl)carbazol-3-yl]ethylideneamino] acetate, or Bis(2,4-cyclopentadienyl)bis[2,6-difluoro-3-(1-pyrryl)phenyl] titanium(IV). The adhesive layer formed from the resin composition RC including the photoinitiator described above may exhibit excellent or suitable reliability.

The resin composition RC may further include a molecular weight modifier. The weight of the molecular weight modifier may be about 0.1 wt % to about 0.2 wt % with respect to the total weight of the resin composition RC. The molecular weight modifier may be a chain transfer agent. For example, the molecular weight modifier may include n-dodecyl mercaptan.

The molecular weight modifier adjusts the length of a polymer chain formed by crosslinking between the monomer and the oligomer, and may adjust the length of the polymer chain such that a relatively short polymer chain is formed. As more polymer chains having a relatively short length are formed, the crosslinking density may become greater. Therefore, in the adhesive layer AL formed from the resin composition RC including the molecular weight control agent, the crosslinking density is increased, thereby preventing or reducing the introduction of foreign substances and the generation of bubbles.

The resin composition RC may further include a UV absorber. As illustrated in FIG. 5, the display devices DD-1, DD-2, DD-3, and DD-4 utilized in a vehicle AM such as an automobile may be affected by the ultraviolet light of sunlight. In order to prevent or reduce damage and/or deformation of the adhesive layer AL by UV rays, the resin composition RC for forming the adhesive layer AL may include a UV absorber.

Table 1 shows results obtained by measuring the creep value and observing the occurrence of bubbles in Experimental Examples and Comparative Examples. Experimental Examples and Comparative Examples in Table 1 each include the anti-reflection member, the adhesive layer (or the preliminary adhesive layer), and the window member described with reference to FIG. 3.

In Table 1, Comparative Example C6, Comparative Example C7, Experimental Example E1, and Experimental Example E2 may each include a preliminary adhesive layer formed by curing the resin composition. Comparative Example C6, Comparative Example C7, Experimental Example E1, and Experimental Example E2 were obtained by providing the preliminary adhesive layer on the anti-reflection member, and providing the window member on the preliminary adhesive layer disposed on the anti-reflection member.

In Table 1, Comparative Examples C1 to C5 each include an adhesive layer formed by curing the resin composition, and in Comparative Examples C1 to C5, the adhesive layer is formed through a single curing process. For example, adhesive layers included in Comparative Examples C1 to C5 are formed by a manufacturing method that does not include forming a preliminary adhesive layer. Comparative Examples C1 to C5 are obtained by providing the adhesive layer on the anti-reflection member, and providing the window member on the adhesive layer disposed on the anti-reflection member.

In Table 1, the creep value was measured with ARES produced by TA Instruments, Inc., and represents the average value of values obtained after five trials. The creep value represents a value obtained when a stress of 1000 Pa is applied at a temperature of 50° C. for 175 seconds. Step bubbles were observed utilizing a microscope, and bubbles generated by concentration of stress on the step were observed. As described above, in the adhesive layer or preliminary adhesive layer that does not cover the step, the stress is concentrated on the step, resulting in bubbles. In Table 1, when bubbles due to the step in the adhesive layer or the preliminary adhesive layer are generated, it is recorded as “generated”, and when bubbles due to the step are not generated, it is recorded as “not generated”.

TABLE 1

| | Comparative | Comparative | Comparative | Comparative | Comparative |
|---|---|---|---|---|---|
| Classification | Example C1 | Example C2 | Example C3 | Example C4 | Example C5 |
| Creep (%) | 2.8 | 5.8 | 10.7 | 5.3 | 5.4 |
| Bubbles by | Generated | generated | Not | Generated | Generated |
| step | | | generated | | |
| | Comparative | Comparative | Experimental | Experimental | |
| Classification | Example C6 | Example C7 | Example E1 | Example E2 | |
| Creep (%) | 33.3 | 33.3 | 33.3 | 33.3 | — |
| Bubbles by | Not | Not | Not | Not | |
| step | generated | generated | generated | generated | |

Referring to Table 1, it may be seen that bubbles are not generated in Comparative Example C3, Comparative Example C6, Comparative Example C7, Experimental Example E1, and Experimental Example E2. In Comparative Example C3, Comparative Example C6, Comparative Example C7, Experimental Example E1, and Experimental Example E2, the creep value with respect to a stress of 1000 Pa was about 10% to about 35%, which satisfies a set or predetermined range of creep values according to one or more embodiments. Accordingly, it is considered that the method of manufacturing a display device including forming a preliminary adhesive layer having a creep value of about 10% to about 35% according to one or more embodiments exhibits excellent or suitable manufacturing reliability. In addition, it is also considered that the display device according to one or more embodiments formed by the method of manufacturing a display device including forming the preliminary adhesive layer having a creep value of about 10% to about 35% exhibits improved reliability.

Referring to Table 1, it may be seen that bubbles were generated in the adhesive layers of Comparative Example C1, Comparative Example C2, Comparative Example C4, and Comparative Example C5. It is considered that the adhesive layers of Comparative Example C1, Comparative Example C2, Comparative Example C4, and Comparative Example C5 each had a creep value of less than 10% and relatively low softness so that the adhesive layers failed to cover the step and bubbles were generated.

Table 2 shows results obtained by measuring stress relaxation values in the adhesive layers of Experimental Examples and Comparative Examples, and observing whether foreign substances were introduced. The adhesive layers of Comparative Examples C1 to C5 in Table 2 may each independently be the same as the adhesive layers of Comparative Examples C1 to C5 in Table 1. The adhesive layers of Comparative Example C6, Comparative Example C7, Experimental Example E1, and Experimental Example E2 in Table 2 were formed by curing the preliminary adhesive layers of Comparative Example C6, Comparative Example C7, Experimental Example E1, and Experimental Example E2 in Table 1.

The adhesive layer of Comparative Example C6 was formed by providing ultraviolet light of 3000 mJ to the preliminary adhesive layer, and the adhesive layer of Comparative Example C7 was formed by providing UV light of 6000 mJ to the preliminary adhesive layer. The adhesive layer of Experimental Example E1 was formed by providing UV light of 6500 mJ to the preliminary adhesive layer, and the adhesive layer of Experimental Example E2 was formed by providing UV light of 7000 mJ to the preliminary adhesive layer.

In Table 2, the stress relaxation value was measured with ARES produced by TA Instruments, Inc., and represents the average value of values obtained after five trials. When measuring the stress relaxation value, adhesive layer samples of Experimental Examples and Comparative Examples were provided in the form of a disk having a diameter of about 25 mm. The stress relaxation value shows the value when a strain of about 25% is applied at a temperature of about 70° C. The stress relaxation value is a value obtained by dividing a second stress by a first stress. The first stress is a stress in a state in which a strain of about 25% is applied for about 0.01 seconds, and the second stress is a stress in a state in which a strain of about 25% is applied for about 300 seconds. In Table 2, the introduction of foreign substances was observed utilizing a microscope, and when foreign substances were observed, it was recorded as “O”, and when foreign substances were not observed, it was recorded as “X”.

TABLE 2

| | Comparative | Comparative | Comparative | Comparative | Comparative |
|---|---|---|---|---|---|
| Classification | Example C1 | Example C2 | Example C3 | Example C4 | Example C5 |
| Stress | 0.70 | 0.38 | 0.23 | 0.30 | 0.30 |
| Relaxation | | | | | |
| Introduction of | X | X | ◯ | X | X |
| foreign | | | | | |
| substances | | | | | |
| | Comparative | Comparative | Experimental | Experimental | |
| Classification | Example C6 | Example C7 | Example E1 | Example E2 | |
| Stress | 0.20 | 0.28 | 0.32 | 0.34 | — |
| Relaxation | | | | | |
| Introduction of | ◯ | ◯ | X | X | |
| foreign | | | | | |
| substances | | | | | |

Referring to Table 2, it may be seen that foreign substances were not observed in Comparative Example C1, Comparative Example C2, Comparative Example C4, Comparative Example C5, Experimental Example E1, and Experimental Example E2. The adhesive layers of Comparative Example C2, Comparative Example C4, Comparative Example C5, Experimental Example E1, and Experimental Example E2 satisfy the range of stress relaxation values according to one or more embodiments. However, the adhesive layers of Comparative Example C1, Comparative Example C2, Comparative Example C4, and Comparative Example C5 had a creep value of less than about 10% in Table 1, which did not satisfy the creep value range according to one or more embodiments. Comparative Examples C6 and C7 had a stress relaxation value of less than about 0.30, and light of less than about 6500 mJ was provided during curing of the preliminary adhesive layer to form the adhesive layer.

Referring to Table 2, the adhesive layers of Experimental Examples E1 and E2 have stress relaxation values of 0.32 and 0.34, which satisfy the stress relaxation value range of about 0.30 to about 0.40 according to one or more embodiments. In Experimental Example E1 and Experimental Example E2, ultraviolet light of about 6500 mJ to about 8500 mJ was provided during curing of the preliminary adhesive layer to form the adhesive layer. It may be seen that compared with Comparative Examples C6 and C7 in which light of less than 6500 mJ was provided, Experimental Examples E1 and E2 exhibit relatively high stress relaxation values. It is considered that in Experimental Examples E1 and E2, which show relatively high stress relaxation values, the crosslinking density was high, and thus foreign substances were not observed.

Table 3 shows results obtained by evaluating the reliability of the adhesive layers of Experimental Examples E1-1 to E1-5 with respect to sunlight, and more specifically, shows results obtained by evaluating of the reliability with respect to ultraviolet light. The adhesive layers of Experimental Examples E1-1 to E1-5 were the same as the adhesive layer of Experimental Example E1 of Table 2, and five adhesive layers of Experimental Example E1 were provided.

Table 3 shows the results according to the standard specification of DIN 75220. One cycle, in which light of 830 W/m 2 is provided to the adhesive layer for 8 hours at a temperature of 85° C. and a relative humidity of 55% (RH), was repeated 45 times. Such an evaluation environment may be similar to an environment in which an adhesive layer of a display device provided in a vehicle is disposed.

In Table 3, ΔT represents the difference between the temperature of the initial adhesive layer and the temperature of the adhesive layer after 45 repetitions, and it is considered that reliability is maintained when the difference is less than 400K. ΔMPCD (Minimum Perceptible Color Difference) relates to a color difference that may be perceived by a human, and when ΔMPCD is 10 or less, it is determined that reliability is maintained. The generation of bubbles was measured by observing with a microscope, whether or not bubbles were generated in the adhesive layer after 45 repetitions, and the case where bubbles were not generated was recorded as ‘not generated’. In Table 3, ‘exposure’ refers to an evaluated result obtained in a state in which the adhesive layer is arranged to be directly exposed to light, and ‘non-exposure’ refers to an evaluated result obtained in a state in which the adhesive layer is covered with silver foil so as not to be directly exposed to light. The conditions of ‘exposure’ and ‘non-exposure’ are to confirm whether the evaluation result is dependent upon temperature or light irradiation.

TABLE 3

| | | | | Generation of |
|---|---|---|---|---|
| Classification | | ΔT(K) | ΔMPCD | bubbles |
| Experimental | Non-exposure | −32 | 0 | Not generated |
| Example E1-1 | Exposure | −8 | −0.2 | Not generated |
| Experimental | Non-exposure | −44 | −0.2 | Not generated |
| Example E1-2 | Exposure | −23 | −0.2 | Not generated |
| Experimental | Non-exposure | −36 | −0.2 | Not generated |
| Example E1-3 | Exposure | 10 | −0.2 | Not generated |
| Experimental | Non-exposure | −26 | −0.2 | Not generated |
| Example E1-4 | Exposure | 20 | −0.2 | Not generated |
| Experimental | Non-exposure | −36 | −0.2 | Not generated |
| Example E1-5 | Exposure | 14 | −0.4 | Not generated |

Referring to Table 3, it may be seen that the adhesive layers of Experimental Examples E1-1 to E1-5 had ΔT of about 400K or less and ΔMPCD of about 10 or less. In addition, it may be seen that in the adhesive layers of Experimental Examples E1-1 to E1-5, bubbles were not generated. It may be seen that ΔMPCD and generation of bubbles in Experimental Examples E1-1 to E1-5 were similar under both the non-exposure condition in which the adhesive layer was not directly exposed to light and the exposure condition in which the adhesive layer was directly exposed to light.

The adhesive layers of Experimental Examples E1-1 to E1-5 were the same as the adhesive layer of Experimental Example E1 in Table 2, and had a stress relaxation value of about 0.30 to about 0.40. The adhesive layers of Experimental Examples E1-1 to E1-5 having a stress relaxation value of about 0.30 to about 0.40 exhibited excellent or suitable crosslinking density, and it is considered that reliability with respect to sunlight is maintained. It is considered that a display device including the adhesive layer of which the reliability with respect to sunlight is maintained exhibits excellent or suitable reliability even when the display device is disposed in a transportation apparatus such as an automobile.

A display device according to one or more embodiments may include an adhesive layer disposed between an anti-reflection member and a window member. The adhesive layer may have a stress relaxation value of about 0.30 to about 0.40 with respect to a strain of about 24% to about 26%. The adhesive layer having a stress relaxation value of about 0.30 to about 0.40 with respect to a strain of about 24% to about 26% may exhibit a high crosslinking density, and thus introduction of foreign substances may not occur. Accordingly, the display device according to one or more embodiments including the adhesive layer may exhibit excellent or suitable reliability.

A method of manufacturing a display device according to one or more embodiments may include curing a resin composition to form a preliminary adhesive layer and curing the preliminary adhesive layer to form an adhesive layer. In one or more embodiments, the preliminary adhesive layer may have a creep value of about 10% to about 35% with respect to a stress of 900 Pa to 1100 Pa, and the adhesive layer formed from the preliminary adhesive layer may have a stress relaxation value of about 0.30 to about 0.40 with respect to a strain of about 24% to about 26%. The method of manufacturing a display device including forming the adhesive layer from the preliminary adhesive layer satisfying the creep value range according to one or more embodiments may ensure improved reliability.

A display device according to one or more embodiments may include an adhesive layer having a relaxation value of about 0.30 to about 0.40 and may exhibit excellent or suitable reliability.

A method of manufacturing a display device according to one or more embodiments may include forming an adhesive layer from a preliminary adhesive layer having a creep value of about 10% to about 35% thereby improving manufacturing reliability.

A vehicle according to one or more embodiments may include a display device according to one or more embodiments including an adhesive layer having a relaxation value of about 0.30 to about 0.40 and may thus exhibit excellent or suitable reliability.

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Further, the use of “may” when describing embodiments of the present disclosure refers to “one or more embodiments of the present disclosure.”

The light emitting device, electronic apparatus or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the embodiments of the present disclosure have been described, it is understood that the present disclosure should not be limited to these embodiments but one or more suitable changes and modifications may be made by one ordinary skilled in the art within the spirit and scope of the present disclosure as defined by the following claims and equivalents thereof.

Accordingly, the technical scope of the present disclosure should not be limited to the content described in the detailed description of the specification, but should be defined by the claims and equivalents thereof.

What is claimed is:

1. A display device comprising:
a display panel;
an anti-reflection member on the display panel;
a window member on the anti-reflection member; and
an adhesive layer between the window member and the anti-reflection member,
wherein the adhesive layer has a stress relaxation value of about 0.30 to about 0.40 with respect to a strain of about 24% to about 26%.

2. The display device of claim 1, wherein the window member comprises:
a window divided into a transmission region and a bezel region; and
a printing layer that does not overlap the transmission region and is on one surface of the window,
the adhesive layer being in contact with a side surface of the printing layer and one surface of the printing layer crossing the side surface of the printing layer.

3. The display device of claim 2, wherein in the bezel region, the printing layer and the anti-reflection member are apart from each other with the adhesive layer therebetween.

4. The display device of claim 2, wherein the adhesive layer has a first thickness in the bezel region, and has, in the transmission region, a second thickness greater than the first thickness.

5. The display device of claim 2, wherein:
the printing layer comprises first to third printing parts sequentially stacked on the one surface of the window;
a first side surface of the third printing part and one surface of the second printing part define a first step, and a second side surface of the second printing part and one surface of the first printing part define a second step; and
the adhesive layer covers the first step and the second step.

6. The display device of claim 1, wherein the adhesive layer comprises a polymer resin derived from a resin composition comprising a monomer, an oligomer, and a crosslinking agent.

7. A method of manufacturing a display device, the method comprising:
preparing a resin composition comprising a monomer, an oligomer, and a crosslinking agent;
forming a preliminary adhesive layer having a creep value of about 10% to about 35% with respect to a stress of about 900 Pa to about 1100 Pa by curing the resin composition;
applying the preliminary adhesive layer on an anti-reflection member on a display panel;
applying a window member on the preliminary adhesive layer on the anti-reflection member; and
forming an adhesive layer by curing the preliminary adhesive layer,
wherein the adhesive layer has a stress relaxation value of about 0.30 to about 0.40 with respect to a strain of about 24% to about 26%.

8. The method of claim 7, wherein, in the forming of the adhesive layer, ultraviolet light of about 6500 mJ to about 8500 mJ is applied to the preliminary adhesive layer.

9. The method of claim 7, wherein, in the forming of the adhesive layer, light passes through the window member and is applied to the preliminary adhesive layer.

10. The method of claim 7, wherein the window member comprises:
a window divided into a transmission region and a bezel region; and
a printing layer that does not overlap the transmission region and is on one surface of the window;
wherein the preliminary adhesive layer is in contact with a side surface of the printing layer and one surface of the printing layer crossing the side surface of the printing layer.

11. The method of claim 7, wherein the oligomer has a weight of about 73.9 wt % to about 84.7 wt % with respect to a total weight of the resin composition.

12. The method of claim 7, wherein the oligomer comprises 2-ethylhexyl acrylate (2-EHA).

13. The method of claim 7, wherein the monomer has a weight of about 15.0 wt % to about 25.0 wt % with respect to a total weight of the resin composition.

14. The method of claim 7, wherein the monomer comprises at least one of 2-hydroxyethyl acrylate (2-HEA), butyl acrylate, isooctyl acrylate, isobornyl acrylate, octyl methacrylate, or benzyl acrylate.

15. The method of claim 7, wherein the crosslinking agent has a weight of about 0.1 wt % to about 0.5 wt % with respect to a total weight of the resin composition.

16. The method of claim 7, wherein the crosslinking agent comprises at least one of 1,6-hexanediol diacrylate (HDDA), pentaerythritol triacrylate (PETA), tripropylene glycol diacrylate (TPGDA), dipropylene glycol diacrylate (DPGDA), tricyclodecane dimethanol diacrylate (TCDDA), tetraethylene glycol diacrylate (TTEGDA), bisphenol F (ethylene oxide)₄ diacrylate, bisphenol A (ethylene oxide)₂₀ diacrylate, bisphenol A (ethylene oxide)₃₀ diacrylate, polyethylene glycol 400 diacrylate (PEG400DA), polyethylene glycol 200 diacrylate (PEG200DA), polyethylene glycol 300 diacrylate (PEG300DA), polyethylene glycol 600 diacrylate (PEG600DA), or polypropylene glycol 400 diacrylate (PPG400DA).

17. The method of claim 7, wherein the resin composition further comprises about 0.1 wt % to about 0.4 wt % of a photoinitiator with respect to a total weight of the resin composition.

18. The method of claim 7, wherein the resin composition further comprises about 0.1 wt % to about 0.2 wt % of a molecular weight modifier with respect to a total weight of the resin composition, and
the molecular weight modifier comprises n-dodecyl mercaptan.

19. The method of claim 7, wherein the resin composition further comprises an ultraviolet (UV) absorber.

20. A vehicle comprising:
a first display device in a first region inside the vehicle and to display first information of the vehicle; and
a second display device in a second region inside the vehicle and to display second information of the vehicle,
wherein at least one of the first display device or the second display device comprises:
a display panel,
an anti-reflection member on the display panel,
a window member on the anti-reflection member; and
an adhesive layer between the window member and the anti-reflection member, and
wherein the adhesive layer has a stress relaxation value of about 0.30 to about 0.40 with respect to a strain of about 24% to about 26%.
